(19) United States
(12) Patent Application Publication
(10) Pub. No.: US 2017/0026029 A1
(43) Pub. Date: Jan. 26, 2017

(54) MULTI-RESONATOR CLOCK REFERENCE

(71) Applicant: Texas Instruments Incorporated, Dallas, TX (US)

(72) Inventors: AHMAD BAHAI, LAFAYETTE, CA (US); ALI KIAEI, SAN JOSE, CA (US); ERNEST TING-TA YEN, SAN JOSE, CA (US)

(21) Appl. No.: 14/807,467

(22) Filed: Jul. 23, 2015

(51) Int. Cl. H03H 9/205

(52) U.S. Cl. CPC H03H 9/205

(57) ABSTRACT

A clock reference includes a substrate, a first resonator and a second resonator both formed on the substrate providing a differential resonator pair. A first variable capacitor is connected across electrodes of the first resonator for electronically tuning a first native frequency of the first resonator to provide a first tuned frequency (f1) and a second variable capacitor is connected across electrodes of the second resonator for electronically tuning a second native frequency of the second resonator to provide a second tuned frequency (f2). A frequency mixer is coupled to receive f1 and f2 for generating a frequency difference signal.

### FIELD

Disclosed embodiments relate to resonator-based clock references.

### BACKGROUND

In electronics and computing, at least one clock reference is generally included to provide a clock signal for synchronizing and scheduling operations. Conventional oscillator architectures used for clock references usually employ in series combination a single resonator providing a high frequency-output, a tuning capacitor for one-time frequency calibration of the resonator, and a frequency divider having a divide factor (e.g., divide by a factor from 10 to 100) selected to generate the output clock reference frequency for a specific application. The resonator can comprise a crystal resonator or a microelectromechanical systems (MEMS)-based resonator.

### SUMMARY

This Summary briefly indicates the nature and substance of this Disclosure. It is submitted with the understanding that it will not be used to interpret or limit the scope or meaning of the claims.

Disclosed embodiments recognize conventional oscillators based on single resonator architectures for clock references have at least two (2) significant problems. First, environment-induced (package stress, temperature, humidity, etc.) changes results in frequency drifts that affect the stability of the output clock signal. Although some of these environmental drift sources can be compensated through device design or feedback control, wafer-level process control still introduces another variation affecting the device performance. Second, the small size of the tuning capacitor and high quality factor (Q) of the resonator limit the typical tuning range of these crystal or MEMS-based resonators to less than one percent, impeding applications requiring a reactively wide tuning range.

Disclosed oscillators solve these problems and provide an oscillator architecture including a pair of high-frequency resonators. Two resonators can be fabricated on the same substrate (or die) to minimize process variations. Rather than using a frequency divider, the output clock frequency is defined by the difference between the respective native frequencies of the resonators in the resonator pair. Since the resonators in the resonator pair can be physically adjacent to one another on the same die, and frequency differencing is used, environment-induced frequency drifts (stress, temperature . . . etc.) tend to cancel out and thus a more frequency stable output clock signal is generated. Although the resonators' respective native frequency tuning range may be relatively small, the output clock signal has a much larger tuning range (100× for example) as compared to conventional clock references.

### BRIEF DESCRIPTION OF THE DRAWINGS

Reference will now be made to the accompanying drawings, which are not necessarily drawn to scale, wherein:

FIG. 1A shows an example clock reference comprising a resonator pair including a first resonator and a second resonator each shown as crystal resonators, according to an example embodiment.

FIG. 1B shows a schematic of an example clock reference comprising a resonator pair including a first resonator and a second resonator both shown as blocks that represent a MEMS resonator.

FIG. 1C shows a depiction of a variable capacitor shown FIGS. 1A and 1B embodied as a capacitor bank.

FIG. 2A is a cross sectional depiction of a thin film bulk acoustic resonator, FIG. 2B is a cross sectional depiction of a solidly mounted resonator, and FIG. 2C is a cross sectional depiction of a solidly mounted resonator with both top and bottom acoustic (Bragg) mirrors.

FIG. 3 shows a side-by-side example dual-BAW resonator including a first BAW resonator and second BAW resonator on a common die.

FIG. 4A shows a conventional single resonator clock reference and FIG. 4B its frequency tuning range shown as ±0.5%.

FIG. 4C shows the example dual-resonator clock reference from FIG. 1A with example frequency values and FIG. 4D its increase in the tuning range from +/−0.5% provided by conventional single resonator clock reference to +/−50% to provide about a 100 times increase in tuning range to provide essentially arbitrary frequency tuning.

FIG. 5 shows package stress induced frequency shift data for a conventional single resonator clock reference and for an example dual-resonator clock reference implementing frequency differencing that reduces the package stress induced frequency shift by about 50%.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

Also, the terms “coupled to” or “couples with” (and the like) as used herein without further qualification are intended to describe either an indirect or direct electrical connection. Thus, if a first device “couples” to a second device, that connection can be through a direct electrical connection where there are only parasitics in the pathway, or through an indirect electrical connection via intervening items including other devices and connections. For indirect coupling, the intervening item generally does not modify the information of a signal but may adjust its current level, voltage level, and/or power level.

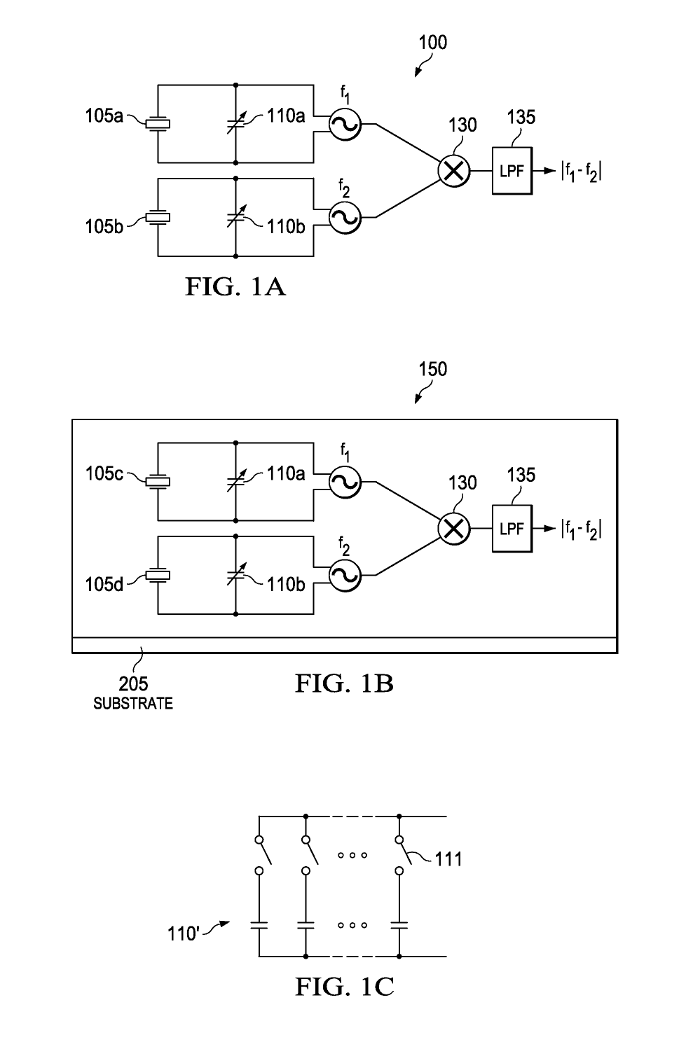

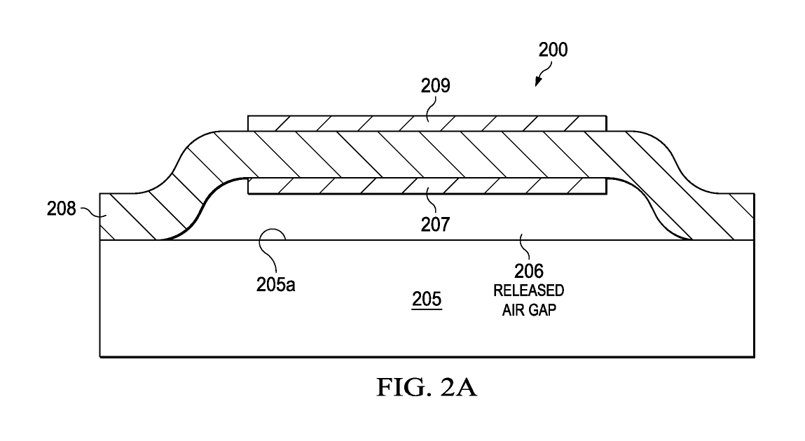

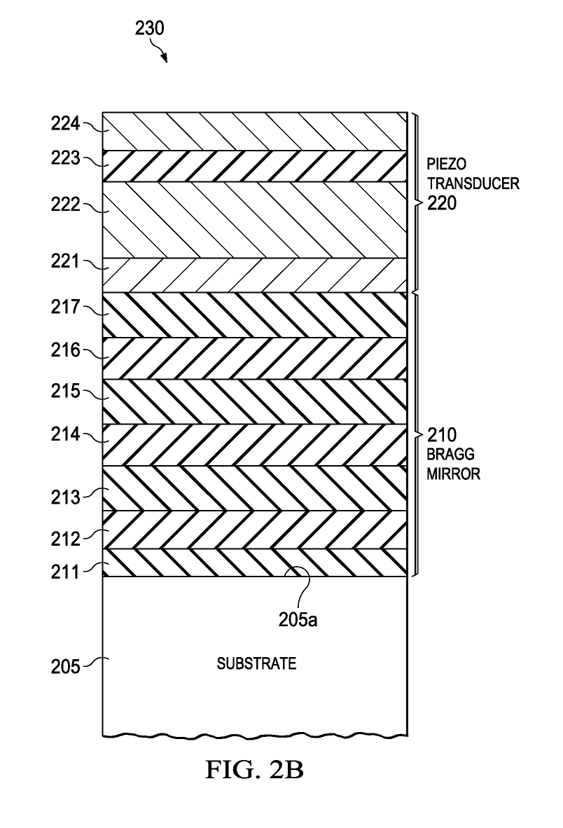

FIG. 1A shows a schematic of an example clock reference 100 comprising a resonator pair including a first resonator 105a and a second resonator 105b, according to an example embodiment. First resonator 105a and second resonator 105b are both shown as crystal resonators. A first variable (i.e., tunable) capacitor 110a (e.g., a capacitor bank) is connected across electrodes of the first resonator for electronically tuning a first native frequency of the first resonator 105a to provide a first tuned frequency (f1) and a second variable capacitor (e.g., a capacitor bank) 110b is connected across electrodes of second resonator 105b for electronically tuning a second native frequency of the second resonator to provide a second tuned frequency (f2) that is different from f1. Although two resonators are shown in FIG. 1A and elsewhere in this application, three or more resonators may also be included.

A frequency mixer 130 is coupled to receive the first tuned frequency and the second tuned frequency for generating a frequency difference signal |f1−f2| that defines a clock reference. For one particular example, with tuned frequencies being 2550 MHz (2.55 GHz) and 2500 MHz (2.5 GHz) frequency differencing generates a nominal 50 MHz output clock reference signal. As described below, due to the tune ability of the variable capacitors 110a and 110b and differencing of the respective tuned frequencies (f1, f2) disclosed clock reference 100 provides a wide-tuning range output clock reference signal.

A frequency mixer 130 (or “mixer”) is known to be a nonlinear electrical circuit that creates new frequencies from two signals applied to it. In its most common application, two signals at frequencies f1 and f2 respectively are applied to the frequency mixer, and the mixer produces new signals at the sum (sum signal) f1+f2 and difference (difference signal) |f1−f2| of the original frequencies, called heterodynes. In one embodiment the tuned frequencies are both from 500 MHz to 10 GHz. For example, for tuned frequencies at 2.55 GHz and 2.5 GHz, |f1−f2|=50 MHz and f1+f2=5.05 GHz.

In some arrangemants, due to a bandwidth limitation of the system the lowpass filtering to filter f1+f2 can occur naturally so there is no need for a lowpass filter (LPF). However, a LPF 135 may be optionally added to the output of the mixer 130 to filter f1+f2 as shown in FIG. 1A. The LPF 135 may comprises a passive or an active filter. The variable capacitors 110a and 110b can be on the same substrate as the mixer 130 and LPF 135, such as on silicon, but need not to be on the same substrate as the first and second resonator 105a, 105b.

FIG. 1B shows a schematic of an example clock reference 150 comprising a resonator pair including a first resonator 105c and a second resonator 105d both formed on a substrate 205 having at least a semiconductor surface, according to an example embodiment. First resonator 105c and a second resonator 105d are both shown as blocks which represent a MEMS resonator that have the advantage of being formed in a CMOS-compatible process which is one advantage over a crystal resonator. The small relative form-factor of MEMS resonators allows co-packaging with another IC in the same package. Moreover, by having the first resonator 105c and second resonator 105d as close as possible on the same die, such a with a≦50 μm lateral spacing, the benefit of cancelling of common mode influences is provided because the respective MEMS resonators experience essentially the same stress and temperature change which thus essentially cancels this drift.

FIG. 1C shows a depiction of a variable capacitor 110a, 110b shown FIG. 1A embodied as a capacitor bank 110′. Each capacitor in the capacitor bank 110′ is shown including a series switch 111 that can comprise a MOS switch. In one arrangement the capacitors in the capacitor bank 110′ have binary weighted capacitances. However, not all capacitors in the capacitor bank 110′ need to include a series switch 111. With all the switches closed, the capitance of capacitor bank 110′ is at its maximum.

Besides quartz crystal tuned resonators a bulk acoustic wave (BAW) resonator (or micro-resonator) is another class of resonator. BAW resonators can be built on same substrate 205 that has at least a semiconductor surface as the other components of clock reference 100. The substrate 205 may comprise silicon, such as bulk silicon or silicon epi on a bulk silicon substrate. The substrate 205 may also comprise other materials, such as elementary semiconductors besides silicon including germanium. The substrate 205 may also comprise a compound semiconductor or a sapphire.

BAW resonators used in this disclosure generally use the piezoelectric effect to convert electrical energy into mechanical energy resulting from an applied radio frequency (RF) voltage. Ideally BAW devices operate at their mechanical resonant frequency which is defined as that frequency for which the half wavelength of sound waves propagating in the device is equal to the total piezoelectric layer thickness for a given velocity of sound for the material BAW resonators operating in the GHz range which have lateral-physical dimensions of tens to hundreds of microns with thicknesses of a few microns.

For functionality the piezoelectric layer of the BAW device is acoustically isolated from the substrate. There are two conventional structures for acoustic isolation of a BAW device. The first conventional structure is referred to as a Thin Film Bulk Acoustic Resonator (FBAR) device. In a FBAR device the acoustic isolation of the piezoelectric layer is achieved by removing substrate material or an appropriate sacrificial layer from beneath the electroded piezoelectric resonating component to provide an air gap cavity.

The second conventional structure for providing acoustic isolation is referred to as a Solidly Mounted Resonator (SMR) device. In an SMR device the acoustic isolation is achieved by having the piezoelectric resonator on top of a highly efficient acoustic Bragg reflector that is on the substrate. The acoustic Bragg reflector includes a plurality of layers with alternating high and low acoustic impedance layers. The thickness of each of these layers is designed to minimize acoustic energy leaking through the substrate. A variant of the SMR device adds a second Bragg mirror on the top of the device to minimized acoustic energy leaking through the package compound and to protect the device from contamination.

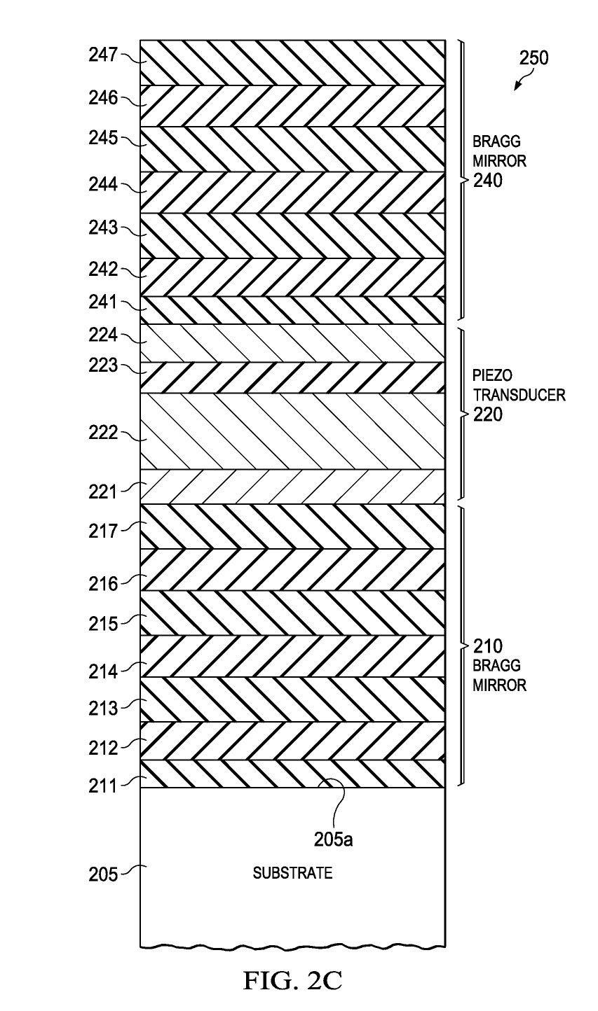

The first resonator 105a and second resonator 105b can both comprise BAW resonators. FIG. 2A is a cross sectional depiction of a FBAR 200 formed on a substrate 205 having a semiconductor surface 205a. A released air gap (air gap) 206 is over the semiconductor surface 205a, a bottom electrode layer 207 is over the air gap 206, a piezoelectric layer 208 is on the bottom electrode layer 207 and on the semiconductor surface 205a lateral to the bottom electrode layer 207 to frame the air gap 206, and a top electrode layer 209 is on the piezoelectric layer 208.

FIG. 2B is a cross sectionional depiction of a BAW resonator embodied as a SMR 230. SMR resonator 230 includes a substrate 205 having a semiconductor surface 205a. A Bragg mirror 210 is on the semiconductor surface 205a. Bragg mirror 210 comprises a plurality of layers with alternating high and low acoustic impedance layers, with the relatively high acoustic impedance layers shown as 212, 214 and 216, alternating with the relatively low acoustic impedance layers 211, 213, 215 and 217. The thickness of each of these layers 211-217 is fixed to be about one quarter wavelength of the desired resonant frequency.

A piezoelectric transducer 220 includes a bottom electrode layer 221 that is on layer 217 of the Bragg mirror 210, a piezoelectric layer 222 on the bottom electrode layer 221, a dielectric layer 223 on the piezoelectric layer 222, and a top electrode layer 224 on the dielectric layer 223.

One possible recognized disadvantage of the SMR 230 described in FIG. 2B is that the top surface of the SMR 230 acts as an acoustic reflector through the properties of a solid/air interface in order to prevent mechanical energy from leaking out of the system from the top side. This means that for a practical SMR resonator for use as a frequency reference/clock there should generally be measures taken to create an air cavity in the final package. However, this is typically a high cost solution involving either hermetic package level technology or hermetic wafer bonding for a wafer level solution. If the final top side air cavity is not hermetically sealed off the resonator can drift in frequency over time as the top surface becomes contaminated through deposition of molecules and/or particles. This problem is overcome in another SMR embodiment illustrated in FIG. 2C described below that has both a bottom Bragg mirror 210 and a top Bragg mirror 240, which is also described in U.S. Pat. No. 6,087,198 entitled “Low Cost Packaging for Thin Film Resonators and Resonator Based Filters” and U.S. Pat. No. 6,548,942 entitled “Encapsulated Packaging for Thin Film Resonators” both to Panasik and assigned to Texas Instruments Incorporated, assignee of this application.

FIG. 2C is a cross sectional depiction of a SMR 250 having both a bottom Bragg mirror 210 and a top Bragg mirror 240, according to an example embodiment. Analogous to bottom Bragg mirror 210, the top Bragg mirror 240 comprises a plurality of layers with alternating high and low acoustic impedance, with the relatively high acoustic impedance layers shown as 242, 244 and 246, alternating with the relatively low acoustic impedance layers 241, 243, 245 and 247. The thickness of each of these layers 241-247 is fixed to be about one quarter wavelength of the desired resonant frequency.

In this embodiment the top Bragg mirror 240 is deposited on top of the SMR 230 shown in FIG. 2B. This results in a SMR 250 which becomes essentially immune to frequency shifts caused by the deposition of contaminants on the piezoelectric transducer 220 and the confining of mechanical energy between the Bragg mirrors 210 and 240. If the top Bragg mirror 240 is efficient enough the frequency of the SMR 250 will not change by more than about 1 part per million (ppm) even if a thick mold compound is used in assembly, being a low cost standard packaging solution, is deposited on top.

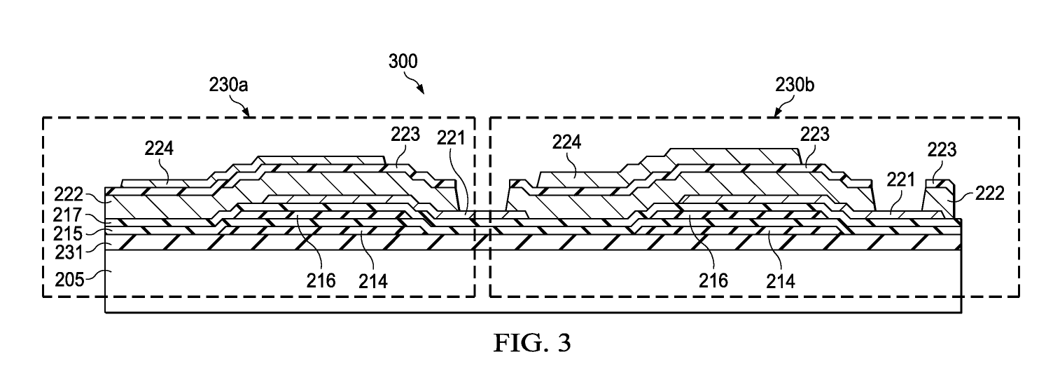

FIG. 3 shows a side-by-side example dual-BAW resonator 300 including a first BAW resonator 230a and second BAW resonator 230b on a common substrate 205 that are each based on the SMR 230 shown in FIG. 2B. A thin thermal silicon oxide layer 231 is shown between the substrate 205 and the acoustic impedance layer 214. A top electrode ion trim technique can be utilized to provide different electrode thicknesses for the top electrode layer 224 for the first BAW resonator 305a and second BAW resonator 305b to fabricate the differential BAW resonator pair by using a frequency trimming mask.

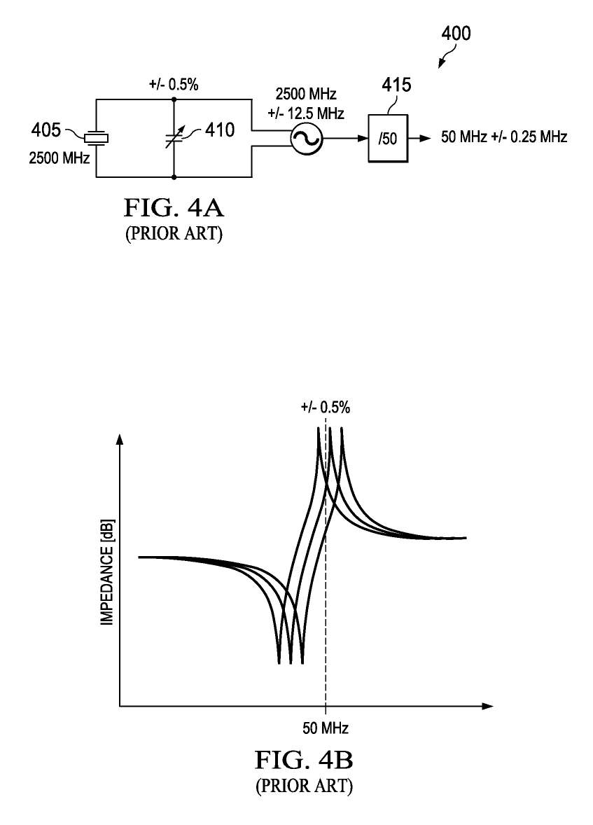

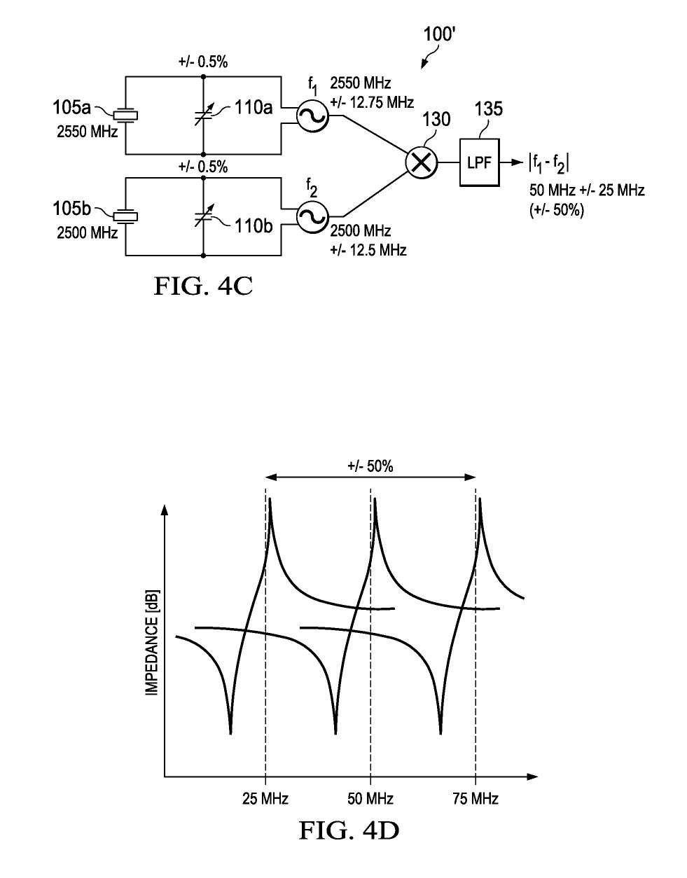

Disclosed embodiments are different compared with other clock reference solutions as they utilize differencing of two (or more) resonators with different native frequencies to generate the output clock signal. No frequency divider is needed in disclosed architectures, and instead a mixer is used for frequency differencing. The two resonators can be physically close to one another on a common die (on one substrate) or physically close to one another in the same package, which reduces environment-induced frequency drifts (e.g., package stress induced frequency shift) or process variations. Separate tuning capacitors (capacitor banks) tune the native frequencies of two resonators individually, providing a relatively large tuning range of the final clock signal described below relative to FIG. 4D. Disclosed architectures can also be adapted to other resonator technologies such as quartz crystal resonators or other MEMS resonators using different materials or transducers.

The temperature coefficient (TC) of the clock reference may be compensated for using same differential arrangement. The principle is essentially the same as cancelling the common mode described above where if two resonators are placed close enough to one another, they experience the same temperature drift. Thus when comparing the absolute frequency difference, this drift can be cancelled at least partially.

Disclosed clock references can be used in any circuit (IC) benefitting from a wide tuning range clock. The clock reference can be on the same chip with the IC, or on a separate chip from the IC but in the same package.

### Examples

Disclosed embodiments are further illustrated by the following specific Examples, which should not be construed as limiting the scope or content of this Disclosure in any way.

FIG. 4A shows a conventional single resonator clock reference 400 including a crystal resonator 405 having a native frequency of 2500 MHz, a tuning capacitor 410, a divide by 50 frequency divider 415, and its tuning range, respectively. The conventional single resonator clock reference 400 has a frequency tuning range that is limited by the size (area) of its tuning capacitor to less than about 1% shown as ±0.5% in FIG. 4B.

FIG. 4C shows the example dual-resonator clock reference 100 from FIG. 1A shown as 100′ with the first resonator 105a having a native frequency of 2550 MHz and a second resonator 105b having a native frequency of 2500 MHz, and other example frequency values. Using the disclosed differential resonator pair provided by dual-resonator clock reference 100′ is seen in FIG. 4D to increase the tuning range from +/−0.5% provided by conventional single resonator clock reference 400 to +/−50% to provide about a 100 times increase in tuning range to provide essentially arbitrary frequency tuning.

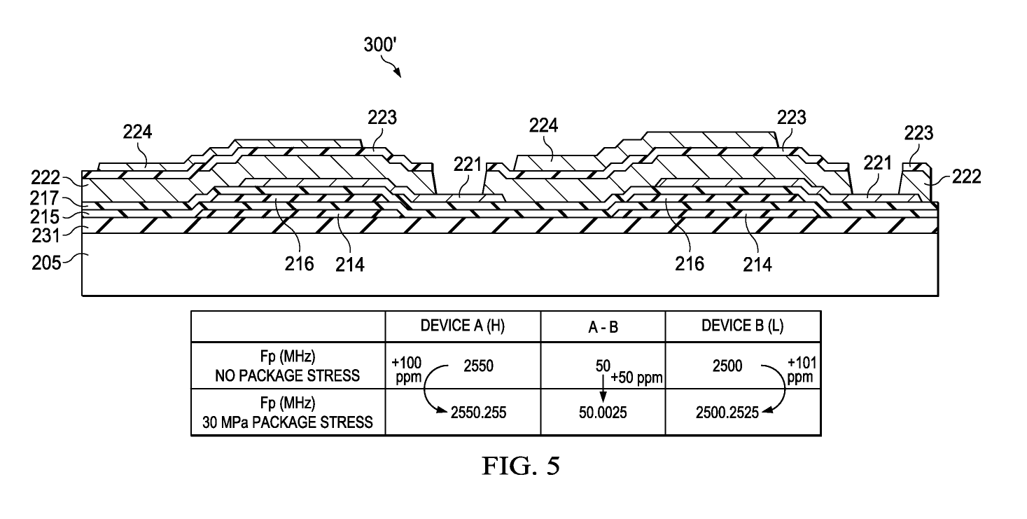

FIG. 5 shows package stress induced frequency shift data for a clock reference from stressing the dual-BAW resonator 300 shown in FIG. 3 shown in FIG. 5 as 300′ and the respective resonators separately. It is assumed the resonator pair shown identified in FIG. 5 shown undergoes the same package-induced stress. A conventional single resonator clock reference shown as Device A and Device B in the table below the dual-BAW resonator 300′ each have a package stress-induced frequency drift of about 100 ppm. The table also shows a dual-resonator clock reference by implementing frequency differencing shown as A-B has a package stress-induced frequency drift of about 50 ppm, which is about a 50% reduction from about 100 ppm of package stress-induced frequency drift from the conventional single resonator clock reference.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A clock reference, comprising:
a substrate;
a first resonator and a second resonator both formed on said substrate providing a differential resonator pair;
a first variable capacitor connected across electrodes of said first resonator for electronically tuning a first frequency of said first resonator to provide a first tuned frequency (f1) and a second variable capacitor connected across electrodes of said second resonator for electronically tuning a second frequency of said second resonator to provide a second tuned frequency (f2), and
a frequency mixer coupled to receive said f1 and said f2 for generating a frequency difference signal.

2. The clock reference of claim 1, wherein said first and second variable capacitor each comprise a capacitor bank having a plurality of capacitors in parallel to another including a series switch for at least some of said plurality of capacitors.

3. The clock reference of claim 1, wherein said first resonator and said second resonator both comprise MEMS resonators, and wherein at least said MEMS resonators, and said frequency mixer are all formed on said substrate.

4. The clock reference of claim 3, wherein said MEMS resonators comprise Solidly Mounted Resonator (SMR) devices.

5. The clock reference of claim 3, wherein said MEMS resonators comprise Thin Film Bulk Acoustic Resonator (FBAR) devices.

6. The clock reference of claim 3, wherein said substrate comprises silicon.

7. The clock reference of claim 1, further comprising a low pass filter coupled to an output of said frequency mixer for filtering a frequency sum signal f1+f2.

8. The clock reference of claim 1, wherein said |f1−f2| is ≦100 MHz.

9. A method of clock reference generation, comprising:
providing a first resonator having a first variable capacitor connected across its electrodes that provides a first tuned frequency (f1) and a second resonator having a second variable capacitor connected across its electrodes that provides a second tuned frequency (f2), and
frequency mixing said f1 and said f2 to generate a frequency difference signal with a frequency equal to |f1−f2|;
wherein said first resonator and said second resonator both comprise MEMS resonators, and wherein at least said MEMS resonators, and a frequency mixer for said frequency mixing are all formed on said substrate.

10. The method of claim 9, further comprising low pass filtering an output of said frequency mixing for filtering a frequency sum signal generated by said frequency mixing equal to f1+f2.

11. The method of claim 9, wherein said first and second variable capacitor each comprise a capacitor bank having a plurality of capacitors in parallel to another including a series switch for selecting or deselecting at least some of said plurality of capacitors, further comprising switching at least one of said series switches.

12. (canceled)

13. The method of claim 9, wherein said |f1−f2| is 100 MHz.

14. The method of claim 9, wherein said MEMS resonators comprise Solidly Mounted Resonator (SMR) devices.

15. The method of claim 9, wherein said MEMS resonators comprise Thin Film Bulk Acoustic Resonator (FBAR) devices.
